(19) United States
(12) Patent Application Publication
(10) Pub. No.: US 2018/0041023 A1
(43) Pub. Date: Feb. 8, 2018

(54) ELECTRICAL SAFETY CONTROL DEVICE

(71) Applicants: Jesus Juvenal Farfan, Valencia (VE); Leonel Wilfrido Farfan, Tamarac, FL (US)

(72) Inventors: Jesus Juvenal Farfan, Valencia (VE); Leonel Wilfrido Farfan, Tamarac, FL (US)

(21) Appl. No.: 15/671,094

(22) Filed: Aug. 7, 2017

Related U.S. Application Data
(60) Provisional application No. 62/371,550, filed on Aug. 5, 2016.

(51) Int. Cl. H02H 3/16; G01R 15/14; H02H 3/33; G05B 9/02; G05B 15/02

(52) U.S. Cl. CPC H02H 3/165; G05B 9/02; G05B 15/02; H02H 3/331; G01R 15/142

(57) ABSTRACT

In order to heighten the level of electrical safety in residential, commercial and industrial networks, stay alert electronic control equipment are needed to detect and report the more common failures in the function of the electric circuitry: high and low line voltage, inversion of the phase sequence in three-phase networks, abnormal current flow between neutral and the ground conductor, and unplanned neutral interruption. When such failures suddenly come about, its effects can provoke harsh damages to users.

The integration in a device of the protection action against different failures such as neutral conductor interruption, a very dangerous and unpredictable failure, high and low voltage failures, phase sequence mistakes, and grounding currents in three phase systems, based on microcontrollers technology and the application of a neutral conductor interruption sensor in three phase systems and in any kind two phase systems improves the electrical safety in any electrical system.

This invention is related with the provisional application No. 62/371,550

### CROSS REFERENCE TO RELATED APPLICATIONS

Related applications may be listed on an application data sheet, either instead of or together with being listed in the specification.

### STATEMENT OF FEDERALLY SPONSORED RESEARCH OR DEVELOPMENT

NA

The names of the parties to a joint research agreement if the claimed invention was made as a result of activities within the scope of a joint research agreement

NA

Reference to a “Sequence Listing,” a table, or a computer program listing appendix submitted on a compact disc and an incorporation by reference of the material on the compact disc. The total number of compact disc including duplicates and the files on each compact disc shall be specified.

NA

### BACKGROUND OF THE INVENTION

Field of the Invention

This invention is related to the field of electrical safety. More specifically, the invention comprises a monitoring and control system to guarantee the operation of industrial, commercial, and residential electrical networks without damages to persons and equipment.

Background

In any electrical facility, there are different types of risk, such as grounding hot wires, short circuits between hot lines, over or under range line voltage, neutral conductor interruptions, or wrong line connections. In order to reduce those risks, and so protect persons and equipment, it is necessary for every instant to measure the line voltages to check voltage balance, ground fault current, and phase sequence. The best voltage balance value is zero; values out of ±5% represent problems to the loads connected to polyphase systems. With the resulting information of the measurement on the electric lines, one of the easiest and more effective ways to implement the protection action is to use a microcontroller functioning with specific software. Also, it is possible to implement a hardware solution, but it should be bulky.

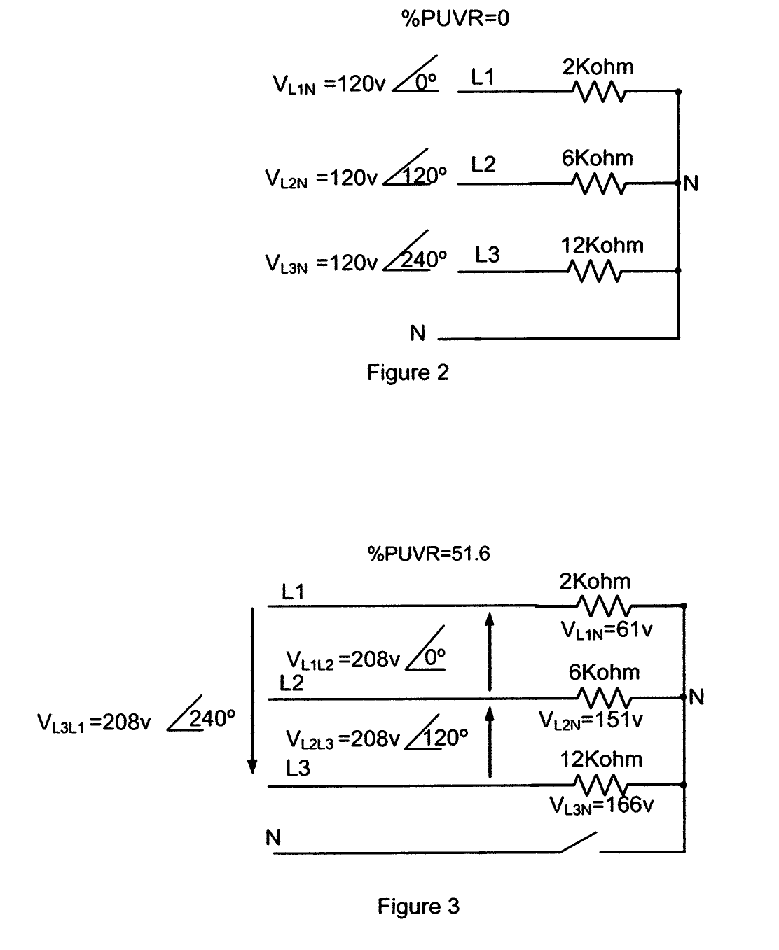

The phase voltage unbalance rate, % PUVR, [((max voltage deviation from avg phase voltage)/(avg phase voltage))*100] is a phase difference independent value. It is applicable to three phase, LLLN, or two phase systems, LLN, 180°, (split phase), or 120°. In a unbalanced load, the neutral conductor interruption or failure affects the % PUVR value, it changes from % PUVR=0 to % PUVR≠0°. In FIG. 2, when the neutral interruption happens, the load changes from a wye load, LLLN, FIG. 2, to a delta load, LLL, as FIG. 3 shows. The phase voltage unbalance rate, % PUVR changes from % PUVR=0 to % PUVR=51.6%. Any % PUVR≠0 may represent, among others problems, a neutral conductor interruption. It does not matter if the line voltage is in or out of the standard range. For testing any unloaded powerlines, LLLN or LLN, by connecting an intentionally very unbalanced load it is possible to get enough information to detect the neutral conductor line condition.

The presence of a ground current means electrical safety problems. The detection of a ground current enables to activate an alarm and disconnects the load in order to avoid any damage. In grounded systems with neutral conductor interrupted, the ground resistance value, affects the voltage unbalance because the neutral current flows through it, in this situations the phase voltage unbalance rate value is, % PUVR≠0.

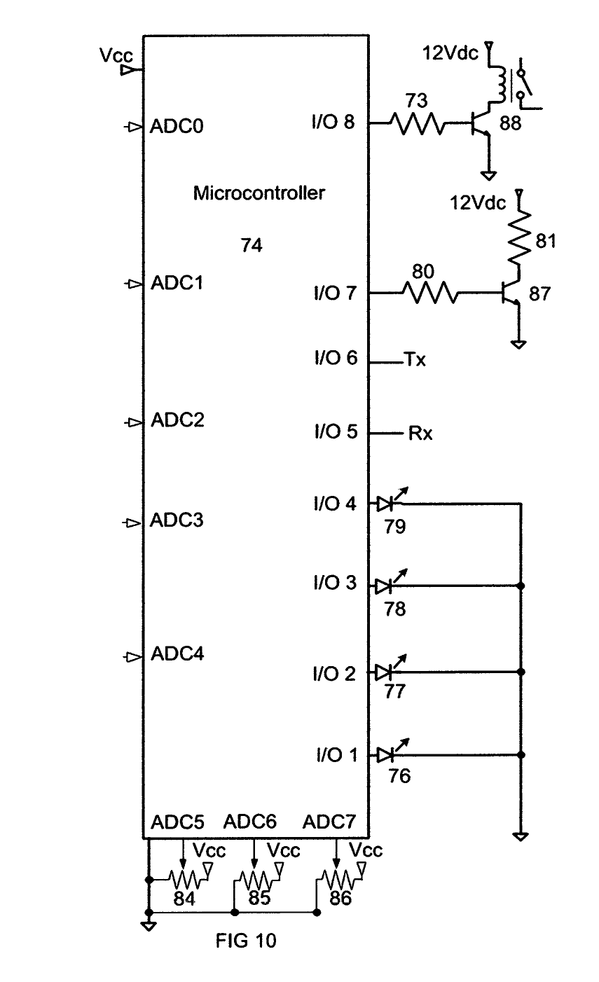

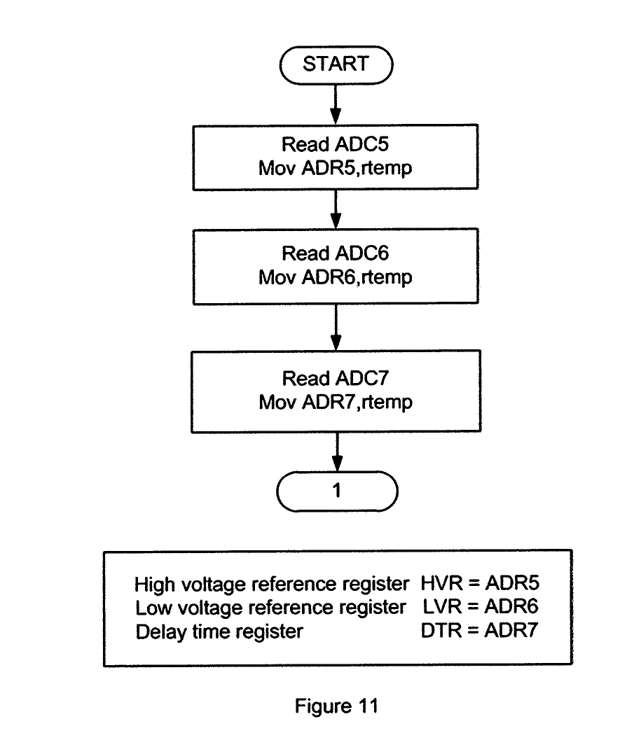

Part of the electrical safety action is to avoid the effects of connection mistakes. Some three-phase loads, like three-phase motors, are sensible to the voltage sequence rotation. Analog or digital solutions are useful to detect the wire position for right phase sequence. FIG. 10 shows the circuit of the analog phase sequence detector implemented in this invention. The voltage output depends on the L₁ and L₂ wire positions in the input circuit. In the right position, Vₒᵤₜ is low, and its value depends on Rc and Cc magnitudes, for the contrary situation, Vₒᵤₜ is high.

### BRIEF SUMMARY OF THE INVENTION

This invention is a poly-phase line condition monitor and a load control device. In order to guarantee the safety of the electrical networks; it is able to detect different parameters variation out of their standard values. The monitoring action of this invention begins when the electrician connects the device to the line, and the load control action through a contactor or similar device depends on the line conditions.

This invention consists of a microcontroller interconnected with different circuits in order to obtain specific information related to the power line conditions at a specific moment and to react in accordance with the information obtained. The reaction may be to connect or to disconnect, automatically, the electrical loads.

This invention uses a wye/delta unbalanced input impedance of a rectifier circuit (half/full wave), that permanently supplies DC energy to one internal voltage regulator. The output of this voltage regulator supplies DC power to every electronic circuit of the invention. The voltage between each wye line terminal and the voltage regulator common terminal determine the voltage balance condition. When the voltage balance value is, in general, over one selected value, ±5% and the neutral conductor is connected, a voltage failure signal starts; when the voltage value is out of range and the grounded conductor is connected, also a voltage failure signal starts. The neutral interruption indicator blinks when, simultaneously, one line voltage is very high, and another line voltage is very low. One phase sequence detector provides phase sequence condition indication; if it is wrong, a phase sequence lamp starts, if not, the lamp is off. For grounded systems, one circuit measures the ground fault current in order to detect a grounding event. When the voltage balance is between ±5 percent, and all the parameters are in normal conditions, the microcontroller automatically connects or keeps connected the load to the power line. When any failure appears, the microcontroller, automatically, disconnects the loads from the wye system acting over a contactor or a similar device. The load connection time is adjustable. The time to disconnect the load is very short.

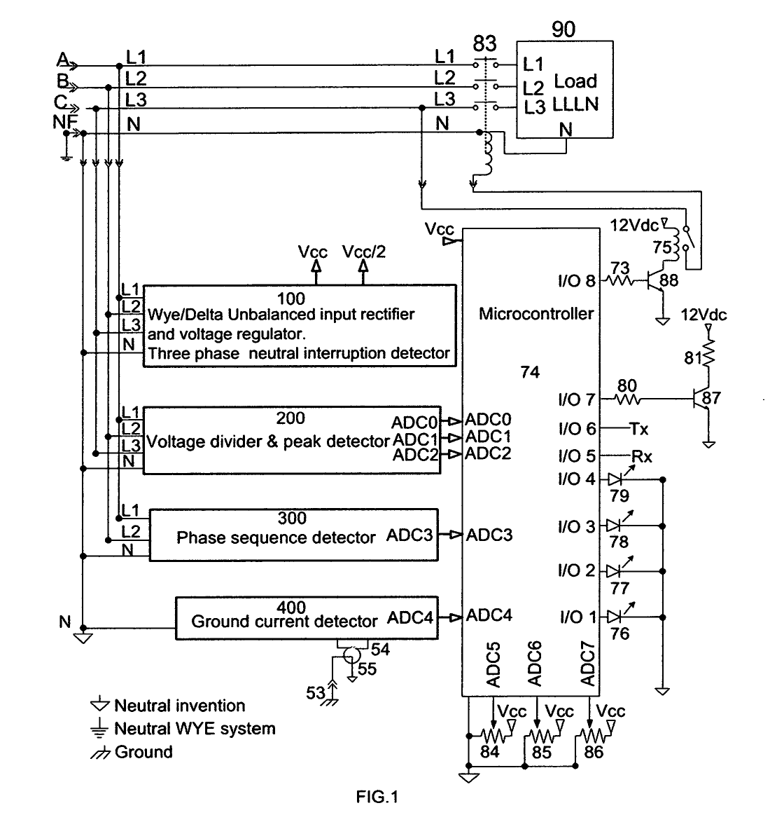

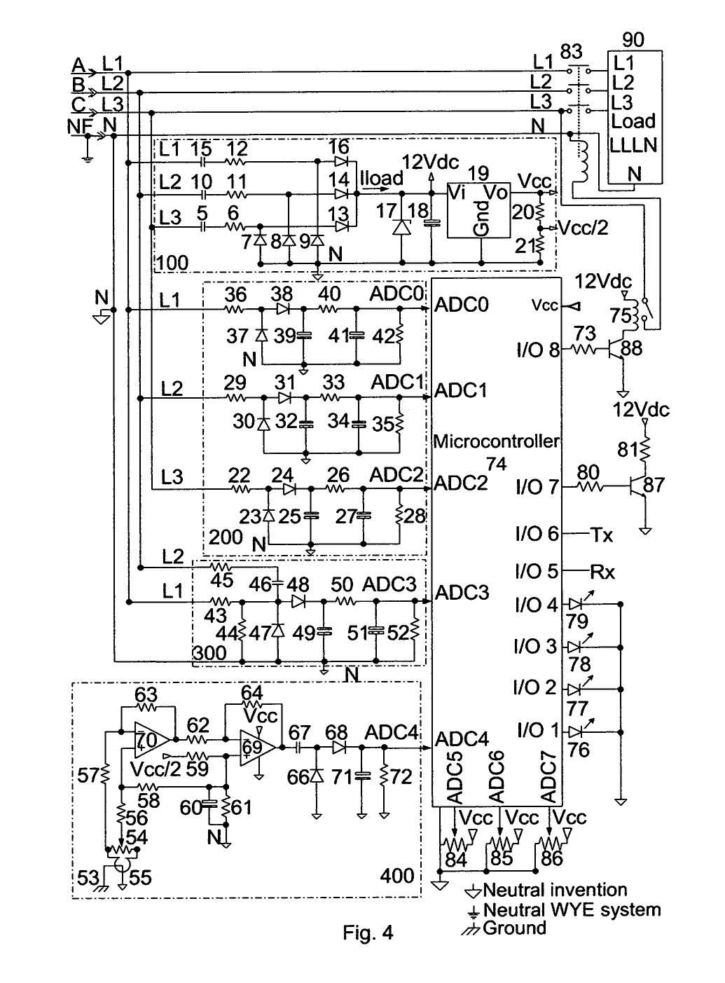

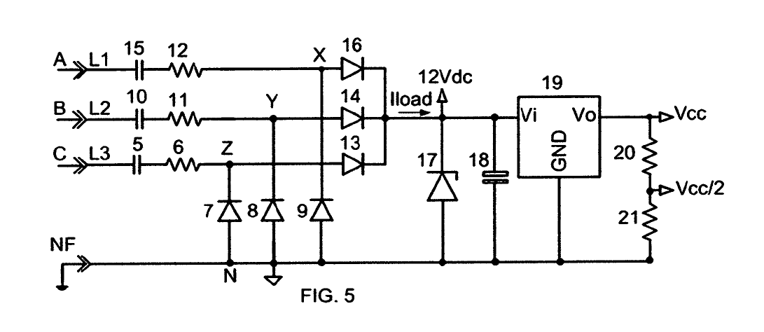

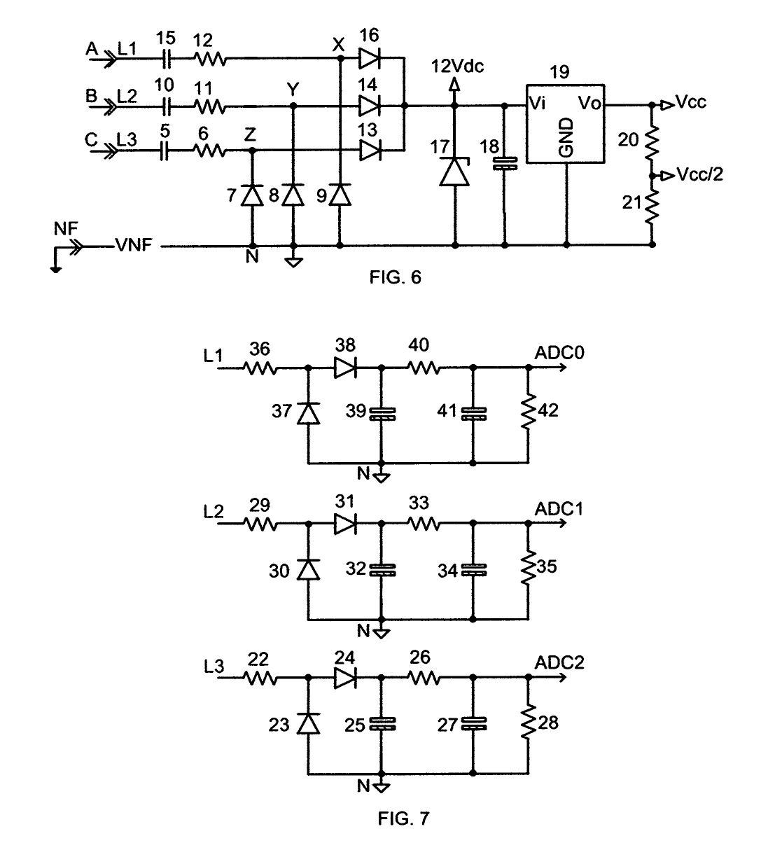

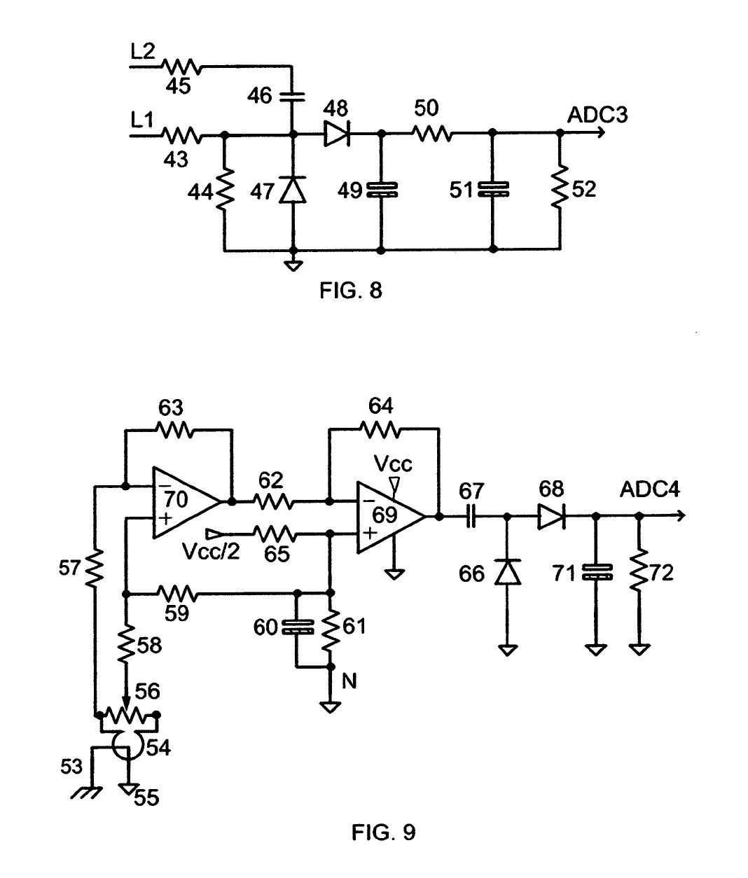

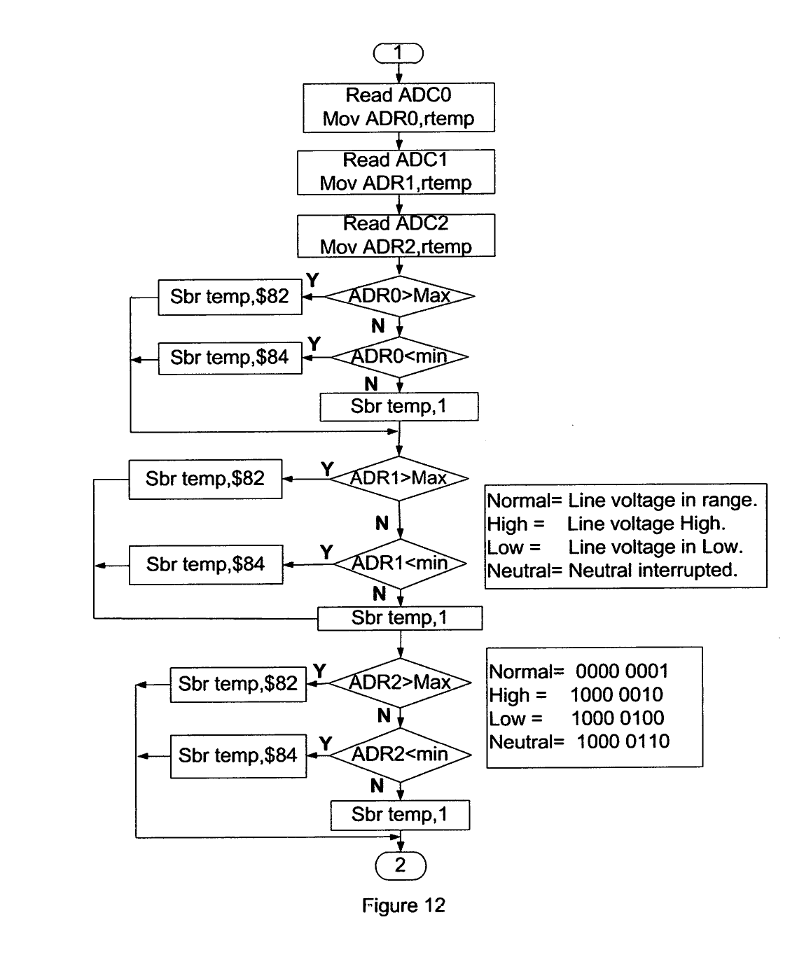

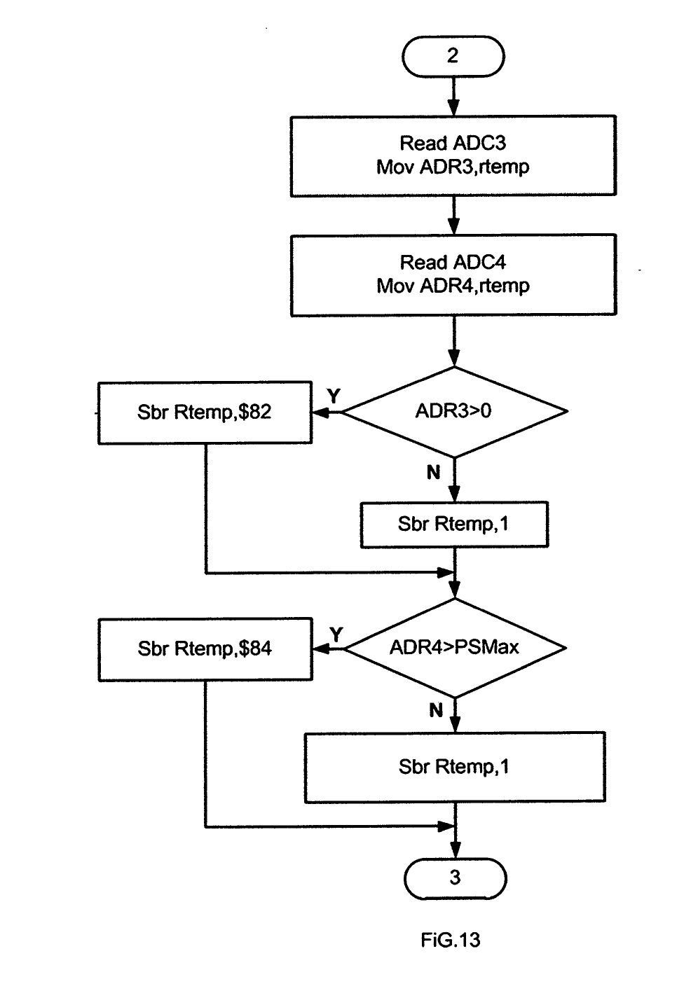

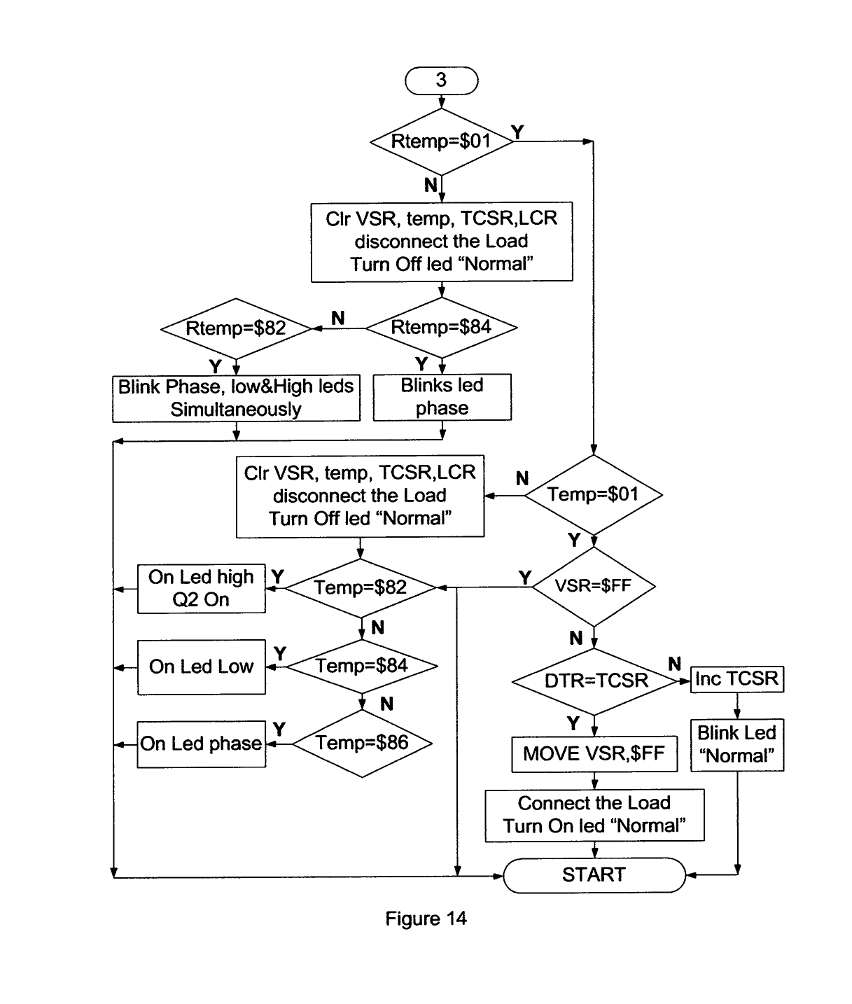

### BRIEF DESCRIPTION OF THE SEVERAL VIEWS OF THE DRAWING

| | |
|---|---|
| Electrical safety control device block diagram | FIG. 1 |
| WYE Load in normal conditions. | FIG. 2 |
| WYE Load in neutral conductor interruption condition. | FIG. 3 |
| Electrical safety control device schematic. | FIG. 4 |
| WYE Unbalanced regulated power supply Normal | FIG. 5 |
| conditions. | |
| WYE Unbalanced regulated power supply Neutral | FIG. 6 |
| conductor interrupted condition. | |
| Voltage divider and peak detector. | FIG. 7 |
| Phase sequence detector. | FIG. 8 |
| Ground fault detector. | FIG. 9 |
| Microcontroller outputs. | FIG. 10 |
| Setting references. | FIG. 11 |
| Reference subroutines | FIG. 12 |
| Voltage subroutine. | FIG. 13 |
| Ground and phase subroutine. | FIG. 14 |

### DETAILED DESCRIPTION OF THE INVENTION

FIG. 8 is a detail from FIG. 4. It shows the ground fault detector of this invention. When a current flows from invention common terminal, 55, N to grounding terminal, 53, the current transformer acts as a current sensor. The secondary pair terminal, the coil side feeds the operational amplifier, 70, with a voltage proportional to the ground current. The variable resistor, 56, controls the output DC voltage magnitude. The ratio (63/57), or (59/58), defines the operational amplifier gain, 70, the single operational amplifier, 69, increases (64/62) times the input voltage value, up to a higher level. The components 66, 67, 68, 71, and 72 rectify the 69 voltage output. The rectifier output supplies its voltage output to the ADC4 microcontroller 74 input that measures the neutral to ground current with the subroutine Grounding alert. FIG. 7 is a detail from FIG. 4. It shows the phase sequence detector connected to the input terminals L1, L2 and N of the wye unbalanced DC power supply. The resistor 43 value is ten times higher than the resistor 44 value. The impedance magnitudes connected to the terminals L1 and L2 are equal. Their angles are 0° for L1 terminal input impedance and 60° for L2 input impedance. The current magnitudes across both impedances are equal. The V_{L1N} voltage angle is 0° and the V_{L2N} voltage angle is 120°. The current across the resistor 43 is in phase with V_{L1N} voltage, its angle is 0°. The current across the series array, resistor 45, capacitor 46, is 60° ahead to V_{L2N} voltage, the final phase angle is 120°+60°=180°. The total current across the resistor 44 is low, because the currents are equal, and the final phase angle is 180°. When the V_{L1N} voltage angle is 120° and the V_{L2N} voltage angle is 0°, the current magnitudes across both impedances are equal. The current across the resistor 43 is in phase with the terminal L1 voltage, its angle is 120°. In the current across the series array, 45, 46, the final phase angle is 0°+60°=60°. The total current across 44 is the angle sum, because the magnitude currents are equal, and the final phase angle is 180°.

A detail from FIG. 4 is depicted in FIG. 5. It shows a three phase wye rectifier circuit and a voltage regulator with three voltage outputs, 12 vdc, Vcc, and Vcc/2. The zener diode 17 and the capacitor 18 limit the maximum voltage and reduce the voltage ripple applied to the voltage regulator 19 input. It provides Vcc volts to the microcontroller 74 and to the operational amplifiers 69 and 70. Resistors 20 and 21 are equals and supply Vcc/2 to the operational amplifiers 69 and 70. In the three phase wye rectifier circuit, when the neutral conductor interruption occurs, in order to detect it, the unbalance phase voltage value has to be higher than zero. The three input impedances have to be very different. In this invention the impedance magnitude connected to the L1 terminal, capacitor 15 and resistor 12, is lower three times than the total impedance magnitude, capacitor 10 and resistor 11, connected to the L2 terminal, and this impedance is lower two times the total impedance, capacitor 5, and resistor 6. The current across capacitor 15 and resistor 12, depends on the voltage difference V_{L1N}−V_{XN} and its value, similarly the current across capacitor 10 and resistor 11, depends on the voltage difference V_{L2N}−V_{YN} and its value, also the current across capacitor 5 and resistor 6, depends on the voltage difference V_{L3N}−V_{ZN} and its value. The voltages V_{XN}, V_{YN}, and V_{ZN} are constant and equals. The voltage magnitude between each line terminal and X, Y or, Z terminal is equals. The current trough the L1 terminal is three times the current trough the L2 terminal, and the current trough the L2 terminal is two times the current trough the L3 terminal. When the neutral conductor is connected, each phase current flows for a period of 5.5 ms from the respective line to the neutral terminal. The phase L₁ current flows for a period of 5.5 ms across the capacitor 15, the resistor 12 and the diode 16 and return to N terminal. The phase L2 current flows for a period of 5.5 ms through the capacitor 10, the resistor 11 and the diode 14 and return to the terminal N. The phase L3 current flows for during 5.5 ms through the capacitor 5, the resistor 6 and the diode 13 and return to the terminal N. The phase voltage magnitudes, V_{L1N}, V_{L2N}, V_{L3N}, are equals.

A detail from FIG. 4 is depicted in FIG. 6. It shows a three phase delta rectifier circuit. The wye rectifier circuit without the neutral conductor is a full wave delta rectifier circuit. The line to line voltage magnitudes, V_{L1L2}, V_{L2L3}, and V_{L3L1} are equal, and V_{L1L2}=1.73 V_{L1N}. for V_{L1N}=120 v, is V_{L1L2}=208 v. The line current flows, for a period of 3 ms, from the L1 terminal across the capacitor 15, the resistor 12 and the diode 16, across the zener diode 17 and the voltage regulator 19 and the other circuits, and return across the diode 8, the resistor 11, the capacitor 10 to the L2 terminal. The voltage (V_{L1N}−V_{XN}) is lower than the voltage (V_{L2N}−V_{YN}), because The current magnitude is the same, and the capacitor 15, resistor 12 total impedance magnitude is three times lower than capacitor 10 and resistor 11 total magnitude.

A detail from FIG. 4 is drawn in the FIG. 7. It shows three standards voltage dividers by a fixed value each one, connected to the input terminals “L1”, “L2”, “L3”, and N of the wye unbalanced DC power supply. For the terminal “L1” in the negative cycle, the current flows from N terminal, through the diode 37, the resistor 36 to the terminal L1. In the positive cycle, the current flows through the resistor 36, diode 38, resistor 40 and from the resistor 42 return to N. The capacitors 39 and 41, act as filters and add a delay time in order to reduce the spikes and false voltage variations. The voltage divider output is the ADC2 microcontroller 74 input. The microcontroller 74 measures the V_{L1N} voltage with the line voltage subroutine. For ADC₀ and ADC₁ operation, the analysis is the same. By this way, the microcontroller 74 with the line voltage subroutine, always measures V_{L1N}, V_{L2N} and V_{L3N}. FIG. 10 is a detail from FIG. 4 that shows the microcontroller 74 inputs/outputs: I/O₀ When any power line voltage goes high, the light “HIGH” starts and the transistor Q₂ turns ON; by this way the zener diode I_{Z} decreases and turns OFF as soon as this condition disappears. I/O₁ It turns ON the led 75 when any power line voltage is low, and it turns OFF as soon as this condition disappears. I/O₂ This is the led 77 it blinks when all the power line voltages are within range and at the end of the preset time, the light turns fixed, and any failure turns it off. I/O₃ In this output, the light 76 blinks for neutral conductor interrupted, and for incorrect phase sequence connection it turns fixed, otherwise, it remains off. I/O₄ When the light 79, is fixed, the transistor Q₁ turns ON, and the relay 75 contacts close in order to energize a contactor or any alarm connected to it, any failure turns off 79, and the relay 75, disconnects the load. I/O₅ Input serial data transmission, Tx. I/O₆ Output serial data reception, Rx. ADCO read V_{L1N}.ADC1 read V_{L2N}.ADC2 read V_{L3N}. ADC3 read phase sequence detector. ADC4 read ground current. ADC5 read the time control trimmer 84ADC6 read the high voltage trimmer 85 ADC8 read the low voltage trimmer 86. In this invention, the microcontroller's analog to digital converters obtain through different circuits all the required electrical data of the monitored system and store each data in a specific register. The microcontroller's resident program uses the different preset references for electrical safety evaluation. The reference subroutine sets the operation limits of the invention. FIG. 11 shows this feature. The reference subroutine through ADC5, ADC6 and ADC7 read the operation limits of the invention set by the trimmers, 84, 85 and 86. The registers ADR5, ADR6, and ADR7 store the data for the remaining process. FIG. 12 shows the voltage subroutine, it handles the line voltage information, the voltages values of V_{Z1N}, V_{Z2N}, and V_{Z3N}, collected by the voltage dividers from the terminals “A”, “B” and “C”. The analog to digital converters, ADC0, ADC1 and ADC2 provide the voltage data to the voltage subroutine; this subroutine uses “temp register” as the status register for storing the voltage line condition. With this information, it is possible to know, partially, the condition of the power line connected to the terminals “A”, “B” and “C”. The ground and phase subroutine handles the ground fault current and phase sequence; ADC3, and ADC4 process their output voltage. This subroutine uses Rtemp as the status register, for storing the grounding fault and phase sequence condition. FIG. 13 shows the ground and phase subroutine. The signal and load control subroutine uses the status registers, “temp and Rtemp data” to activate the indicators alarms. The ground fault is the first priority alarm, followed by the phase sequence and later on by the voltage alarms. In normal condition, the load connection time depends on the preset by the 56 trimmer. FIG. 14 shows the signal and load control subroutine.

### SEQUENCE LISTING (IF ANY)

NA

1. An electrical safety device for Wye three phase systems, which continuously measure the powerline phase voltages, the phase sequence condition, and ground current in order to protect against neutral conductor interruption, high or low voltage failures, phase sequence mistakes and ground.

2. An electrical safety control device of claim 1, wherein an very unbalanced input impedance wye delta rectifier a voltage regulator and neutral conductor interruption sensor that works as follows when wye system, LLLN, with its rightly bonded neutral conductor; in this case, the unbalanced phase voltage is zero and the voltage measured between the common conductor of the network and each line is the same. When the neutral is suddenly interrupted, the phase voltage becomes abnormally high in a particular line whereas at the same time, in other line the voltage results abnormally low. This facts mean that the voltage measured between a line and the its neutral is too high and, simultaneously, the voltage measured between another line and its neutral is too low. This sensor also is applicable in any kind of two phase system.

3. An electrical safety control device of claim 2, where in a three phase neutral sensor based on three very different input impedances connected, through voltage dividers and rectifiers, to three analog to digital converters to measure continuously the phase voltage of the wye three phase system, and to process the voltage data with a microcontroller with the appropriate software in order to determine the neutral conductor condition, phase voltage value, the voltage phase unbalance value, and connect or disconnect the load, a variable time depending on the voltage line conditions.

4. An electrical safety control device of claim 1 where in two lines of a wye system are connected to two equal magnitudes and the impedance angles respectively 0° and 60°, and their other side are connected to a resistor of value ten times lower than both impedances value. The voltage in the small resistor is rectified and connected to one analog to digital converter that provides the data to a microcontroller that process the information with a specific software in order to identifie the phase sequence condition. A low voltage means a right phase sequence, and the load may be connected.

5. An electrical safety control device of claim 1 where in a current transformer measure the current in a wire connected between the electrical safety control device neutral and a terminal grounded, the current value is amplified, rectified and connected to one analog to digital converter that provide the data to a microcontroller that process the information with a specific software in order to make decision depending on the ground current value.
